(19) United States
(12) Patent Application Publication
(10) Pub. No.: US 2006/0256509 A1
(43) Pub. Date: Nov. 16, 2006

(54) Inner door space communication assembly and a method for exchanging signals

(76) Inventor: Yoav Shilo, Tel-Mod (IL)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/127,957

(22) Filed: May 11, 2005

(51) Int. Cl. H05K 5/00

(52) U.S. Cl. 361/679

(57) ABSTRACT

A communication assembly that includes a backplane; and multiple boards coupled to the backplane such that at least one board is coupled to one side of the backplane while at least one other board is coupled to a second side of the backplane; wherein the backplane and the multiple boards are shaped and are positioned such as when the backplane and the multiple boards are coupled to each other they provide a thin communication assembly that can be installed in a door space of existing communication cabinet. A communication cabinet that includes a door comprising inner walls that define a substantially shallow inner door space, and a communication cabinet that comprises a backplane and multiple boards coupled to the backplane; wherein the backplane and the multiple boards are shaped and are positioned such as to fit within the inner door space. A method for exchanging electrical signals, the method includes: providing signals to inner door space communication equipment that is at least partially positioned within an inner space defined by a communication cabinet door; and receiving signals from the inner door space communication equipment, wherein the inner door space communication equipment comprises a backplane and multiple boards coupled to the backplane.

### FIELD OF THE INVENTION

The present invention relates to communication assemblies and especially to multiple PCB communication assemblies.

### BACKGROUND OF THE INVENTION

Recent development in the communication field reduced the cost of communication services while dramatically increased the volume of information being conveyed over communication networks. Multiple broadband technologies facilitate fast transmission of multimedia content to end users.

The communication market is highly competitive. In order to attract clients the communication services must be relatively cheap. The cost of these services is largely influences by the cost of maintaining, replacing and even replacing communication infrastructure. This infrastructure usually includes a large amount of communication cabinets in which multiple communication circuits are placed.

A typical communication chassis is relatively deep and wide, in order to allow multiple boards (also known as PCBs) to be vertically installed in parallel to the side walls of the cage. The chassis usually includes a series of slots on its top wall and on its bottom wall into which the PCBs are slid. The PCBs are electrically connected, via connectors, to a backplane located at the rear of the chassis.

U.S. Pat. No. 5,930,111 of Yamazaki et al., U.S. Pat. No. 6,396,990 and European patent 987905A2 of Kutsch et al. describe various prior art communication cabinets and communication equipment.

Due to ever growing rise increase of end-users and end user demands, as well as the dramatic increase in communication services capacity there is a need to provide an efficient manner to upgrade existing communication infrastructure.

The upgrade may include replacing old boards with new and more capable boards. The upgrade may include, additionally or alternatively, adding more boards to the existing communication chassis.

Both solutions are limited by the amount of vacant space defined by the various walls of the communication cabinet. In many cases communication cabinets are filled with equipment and do not have enough vacant space to allow an installment of additional communication chassis.

There is a need to provide an efficient manner for upgrading existing communication cabinets.

### SUMMARY OF THE PRESENT INVENTION

A communication assembly that includes a backplane and multiple boards connected to the backplane such that at least one board is coupled to one side of the backplane while at least one other board is coupled to a second side of the backplane; wherein the backplane and the multiple boards are shaped and are positioned such as when the backplane and the multiple boards are coupled to each other they provide a thin communication assembly.

A method for installing a communication assembly, the method includes: providing a communication assembly that includes a backplane and multiple boards connected to the backplane; wherein the backplane and the multiple boards are shaped and are positioned such as when the backplane and the multiple boards are coupled to each other they provide a thin communication assembly; and connecting the communication assembly to a door of a communication cabinet.

A method for exchanging electrical signals, the method includes: providing signals, by inner door space communication equipment that is at least partially positioned within an inner space defined by a communication cabinet door; wherein the communication equipment includes a backplane and multiple boards that are coupled to the backplane; and receiving signals, by the inner door space communication equipment.

A method for exchanging electrical signals, the method includes: providing signals to inner door space communication equipment that is at least partially positioned within an inner space defined by a communication cabinet door; and receiving signals from the inner door space communication equipment; wherein the inner door space communication equipment includes a backplane and multiple boards coupled to the backplane.

### DESCRIPTION OF THE DRAWINGS

The present invention will be understood and appreciated more fully from the following detailed description taken in conjunction with the drawings in which:

FIG. 1 illustrates a portion of a communication cabinet according to an embodiment of the invention;

FIGS. 2-4 and illustrate a communication assemblies and communication equipment, according to an embodiment of the invention;

FIG. 5 is a cross sectional view of a portion of the communication cabinet, according to an embodiment of the invention; and

FIGS. 6-7 are flowcharts of methods for exchanging signals, according to various embodiments of the invention; and

FIG. 8 is a flow chart of a method for installing a communication assembly, according to an embodiment of the invention.

### DETAILED DESCRIPTION OF PREFERRED EMBODIMENTS

The invention provides a thin communication assembly that can fit, for example, within communication cabinet doors. The thin communication assembly includes communication equipment such as multiple boards as well as a long and narrow backplane that connects the multiple boards to each other. The communication assembly may also include a housing.

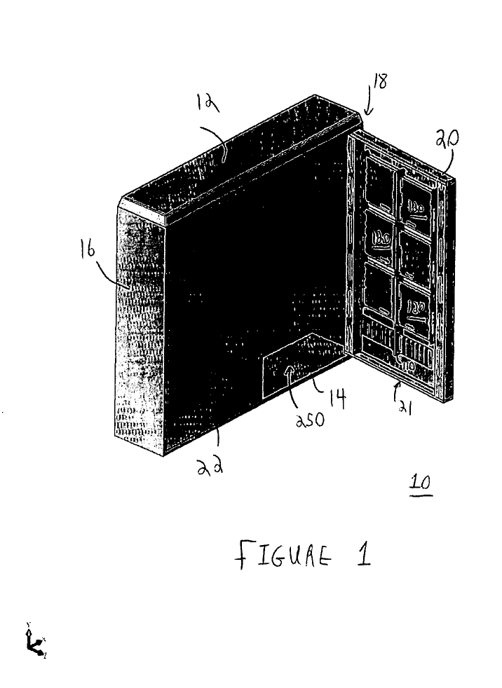

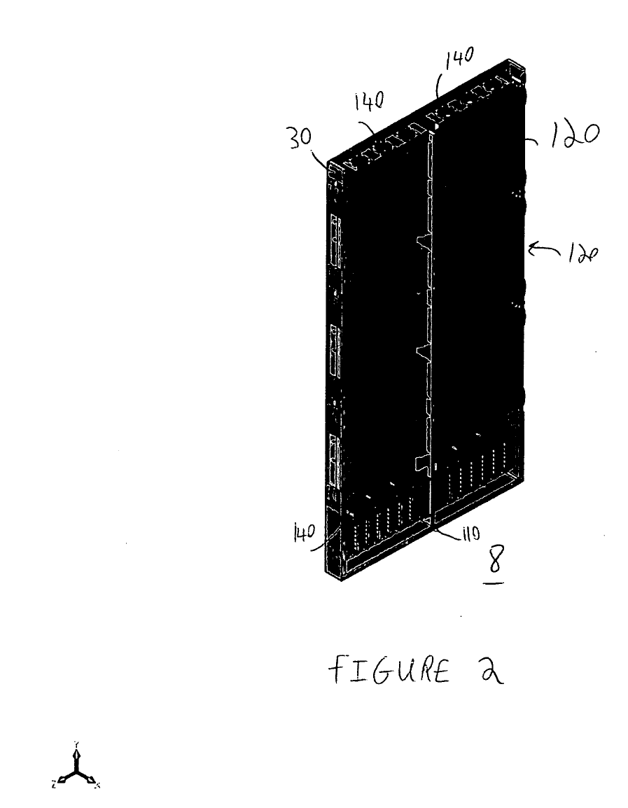

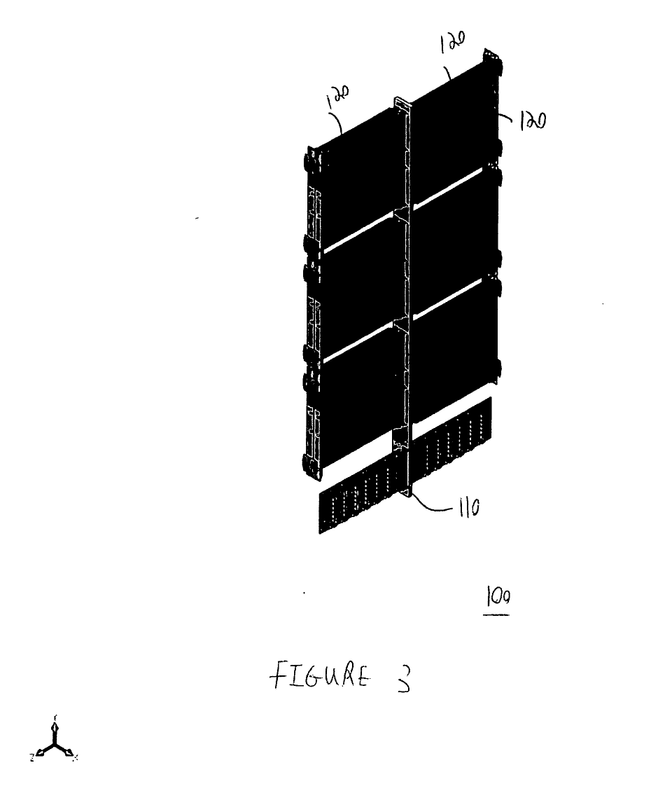

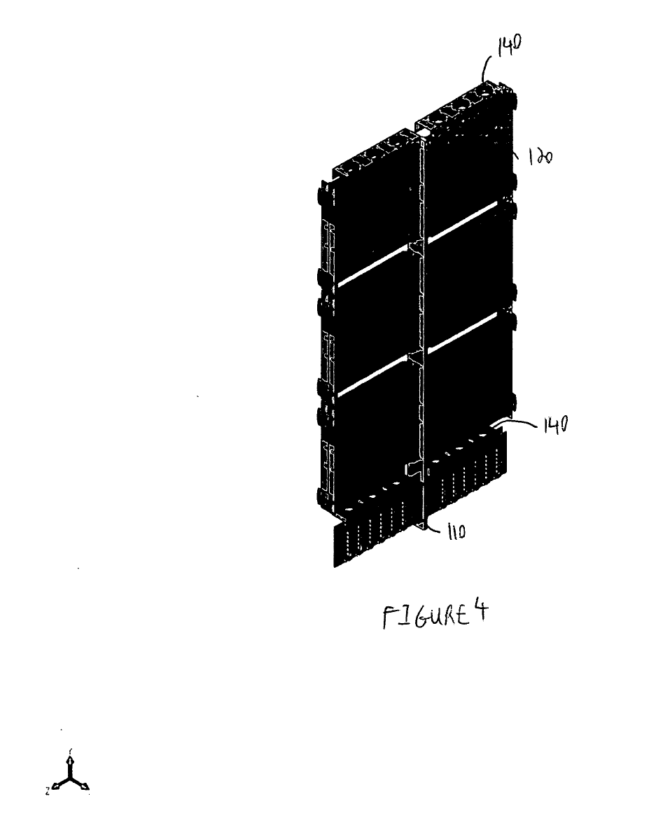

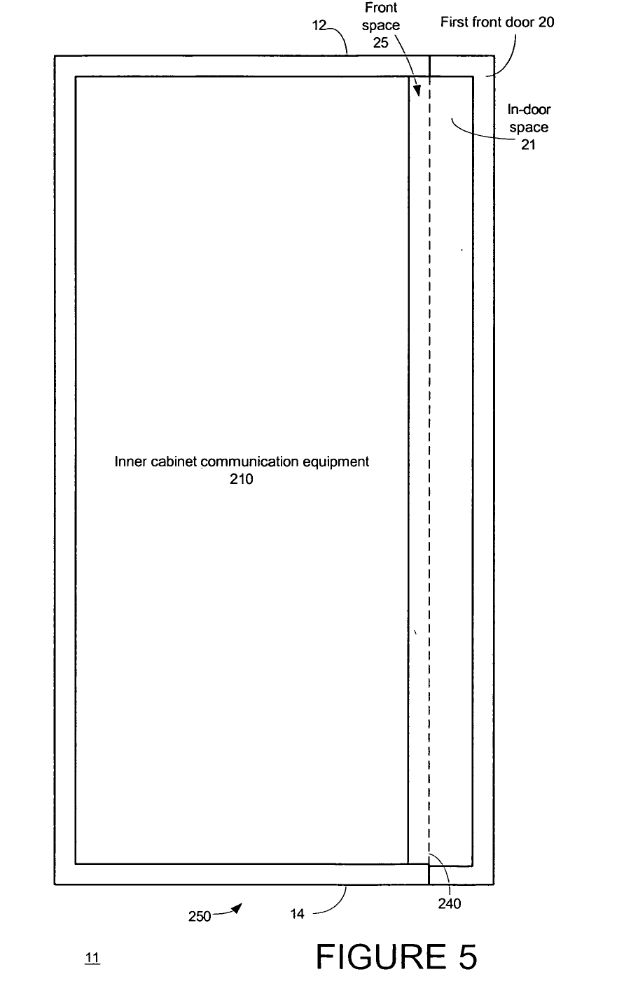

FIG. 1 illustrates a communication cabinet 10, FIG. 2 illustrates a communication assembly 8. FIGS. 3-4 illustrates communication equipment 100. FIG. 5 illustrates a cross sectional view of a communication cabinet, all according to various embodiments of the invention.

It is noted that all Figures, and especially FIG. 5 are not necessarily in scale.

Communication cabinet 10 has two front doors 20 and 22. Each front door defines an inner space in which the thin communication assembly 8 can fit. For simplicity of explanation the following description will relate to a first space defined by the first door 20, but the same can be applied to the second door. It is further noted that the communication cabinet can have various configurations other than the configuration that is illustrated in FIG. 1. For example, the communication cabinet 8 can have side doors in which communication assemblies may fit. Yet for another example, the communication cabinet may include a single door or more than three doors.

Conveniently, multiple doors are pivotally connected to the communication assembly, but this is not necessarily so. For example, the communication cabinet can include a sliding door that can slide such to allow easy access to the communication assembly.

The inventors used a BroadAccess™ communication cabinet of Teledata networks. The BroadAccess™ family includes a large variety of communication cabinets of different size that include one or more communication cages (also referred to as communication chassises), and can support between sixty-four subscriber lines and one thousand and nine hundred subscriber lines.

The communication cabinet 10 can be installed outdoor or indoor, and can be mounted in various manners including wall mounting, pad mounting and floor level mounting. It is noted that the invention can be applied in other communication cabinets of the BroadAccess™ family, as well as in other communication cabinets.

Cabinet 10 has a rectangular shape. It has an upper wall 12, a lower wall 14, two side walls 16 and 18. The front edge of each of these walls 12-18 defines an imaginary communication cabinet front plane. Walls 12-18 and the imaginary communication cabinet front plane define an inner cabinet space. Multiple structural elements such as but not limited to multiple panels, as well as communication equipment (referred to as inner cabinet communication equipment 210) are located within the inner cabinet space.

Typically, the inner cabinet space includes multiple interior spaces, defined by the structural elements. The inner cabinet communication equipment usually includes inner cabinet communication chassis, power supply units and the like.

Cabinet 10 has two pivotally connected front doors 20 and 22. Each door of 20 and 22 has a recessed shape such as to define an inner door space. FIG. 1 illustrates an open first front door 20 in which communication equipment 100 is placed. Each of the inner door spaces and optionally corresponding front spaces define larger spaces in which communication assembly can be installed.

Typically, the communication cabinet 10 interfaces one or more networks. One or more cables interconnect the inner cabinet communication equipment 210 and optionally inner door space communication equipment 100, to these one or more networks. The communication cabinet 10 is also connected to one or more power supply.

According to one embodiment of the invention the inner door space communication equipment 100 is wholly located within a first inner door space 21. According to another embodiment of the invention the inner door space communication equipment 100 extends out of the door.

According to various embodiments the inner door space communication equipment 100 can be directly or indirectly connected to the power and/or communication cables. The inner door space communication equipment 100 can be connected to inner cabinet communication equipment, but this is not necessarily so.

Typically, there are one or more empty front spaces, that are at least few centimeters deep. These front spaces are defined by the front portion or front panels of the inner cabinet communication equipment and the imaginary communication cabinet front plane.

FIG. 5 illustrates a cross sectional view of a portion 11 of the communication cabinet 10 that includes a front door 20, an inner door space 21 defined by the first door 20 and inner door space communication equipment 210 located within the inner cabinet space 250. FIG. 5 also illustrates front space 25 and the imaginary communication cabinet front plane 240.

According to an embodiment of the invention the communication assembly 8 is designed such as to fit into inner door space 21. The communication assembly 8 may be smaller than the inner door space 21 but this is necessarily so and it can virtually fill the whole first inner door space 21. According to another embodiment of the invention the communication assembly 8 is designed such as to fit into a larger space defined by inner door space 21 and a corresponding front space 25.

According to an embodiment of the invention the communication assembly 8 includes a housing 30 that at least partially surrounds communication equipment 100 such as backplane 110 and multiple boards 120. This not necessarily so and the housing can be shaped and positioned such as not to even partially surround the communication equipment 100. For example, the housing 30 can only include a panel that is positioned between the inner door space communication equipment 100 and the inner cabinet communication equipment 210. FIG. 2 illustrates a communication assembly that includes communication equipment 100 that includes a backplane 110 and two rows of boards 120 connected to each side of the backplane 110. The communication assembly includes twelve fans 140, six fans 140 positioned above the boards 120 and six fans positioned below the boards 120 but above a lower panel to which various connectors 145 are located. The connectors 145 are to be connected to power and communication cables (not shown) that are connected on their other ends to inner cabinet communication equipment and/or to cables that are directly connected to components outside communication cabinet 8. FIG. 2 illustrate a housing 30 that includes various panels, including a back panel that faces the communication cabinet inner space 250 and can be used to almost seal communication equipment 100 placed within the first front door 20, as well as thin side panels and a lower panel.

According to another embodiment of the invention the communication assembly 8 does not include housing 30 but only includes the backplane and connected boards.

FIG. 9 illustrates housing 30 in which the communication equipment 100 in placed. Housing 30 is conveniently water proof. Conveniently, the housing 30 has multiple openings. Communication wires and power cables pass through some of the openings. Other openings are used for ventilation.

Housing 30 is connected to the left door 20, and typically another housing (not shown) is connected to the right door 22 of cabinet 10.

According to an embodiment of the invention the communication equipment 100 located within housing 30 is cooled by fans installed within the housing, and/or by fans that are mounted on or other wise are placed in the vicinity of housing 30. FIGS. 2 and 4 illustrates fans 140 that are connected to the housing 30.

According to another embodiment of the invention the communication equipment within housing 30 is cooled by one or more fans that are positioned outside the first inner door space 210.

Conveniently, housing 30 has shock absorbing components, such as but not limited to springs, that are connected between certain portions of housing 30 and first door 20, such as to reduce the impact or shock resulting from closing or opening the door 20 or from hits or other impacts on door 20.

FIG. 2 illustrates communication assembly 100 according to an embodiment of the invention. Communication assembly 100 includes a long and narrow backplane 110 that is connected to multiple boards 120, each including multiple integrated circuits. The backplane 110 can include structural elements such as rigid plane, can have multiple layers, and also includes electrical and/or optical circuitry.

The backplane 110 is connected to boards 120 by connectors. At least some of connectors provide structural support to at least some of the boards 120. At least a part of the connectors provide power to the boards and also electrically (or optically) connect the boards to backplane 110. The connectors can be of any kind known in the art. It is noted that a single connector can provide structural support to a board and also electrically or optically connect that board to the backplane but this is not necessarily so.

Some of the connectors used by the inventors had a rectangular shape and were fastened to the backplane 110 by screws. These connectors were connected on one side to the backplane 110 while an adjacent side of each connector was fastened to the board 120 by a screw.

The upper part of communication assembly 100 includes a vertical backplane 110 that is wide enough to support two rows of boards on each side, but is narrow enough to fit in the inner space of door 20. The lower part of communication assembly 8 includes multiple connectors 145 for receiving power and signal cords and/or wires from the cabinet.

According to another embodiment of the invention the angle between the backplane 110 and the boards 120 is not ninety degrees. For example, the backplane can be positioned in parallel to the boards 120 while “L” shaped connectors, panels and the like, can connect the backplane 110 to the boards 120.

According to another embodiment of the invention the backplane 110 is not located at the center of multiple boards 120. This backplane 110 can have boards on one side only.

According to another embodiment of the invention the communication equipment 100 can include multiple backplanes and/or backplane portions. They can be positioned apart from each other, grouped together and the like.

Connectors of the communication equipment 100 are connected to corresponding cables' connectors within the cabinet. Conveniently, when door 20 is opened some of these cables loosely hang between these connectors. The cables are long enough to allow the door to be opened to a certain position.

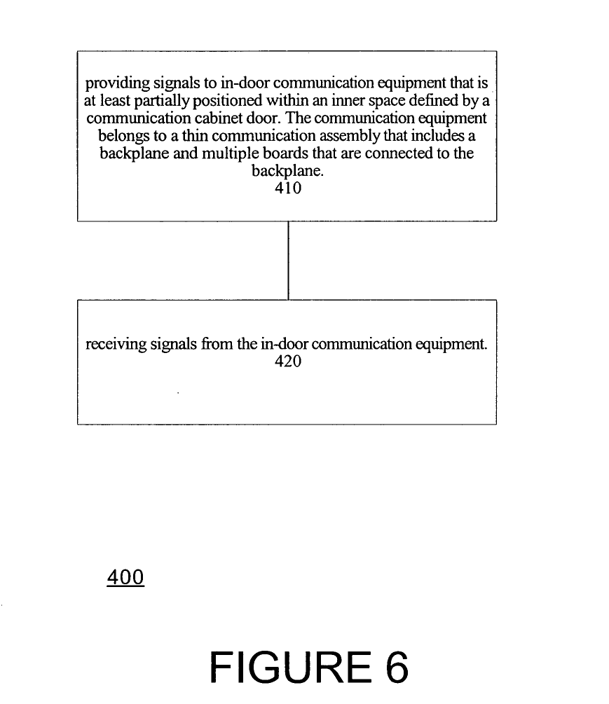

FIG. 6 is a flow chart of a method 400 for exchanging electrical signals, according to an embodiment of the invention. Method 400 starts by stage 410 of providing signals to inner door space communication equipment that is at least partially positioned within an inner space defined by a communication cabinet door. The communication equipment belongs to a thin communication assembly that includes a backplane and multiple boards that are connected to the backplane.

According to an embodiment of the invention the signals can include telecommunication signals such as optical or electronic signals, they can also include power feeding. Conveniently, the inner door space communication equipment exchanges signals with inner cabinet communication equipment and/or with equipment located outside the communication cabinet, via cables or even by wireless communication means. Thus, a single board can exchange some signals with another boards or boards that belong to the inner cabinet communication equipment and also exchange signals directly with equipment located outside the communication cabinet.

Stage 410 is followed by stage 420 of receiving signals from the inner door space communication equipment.

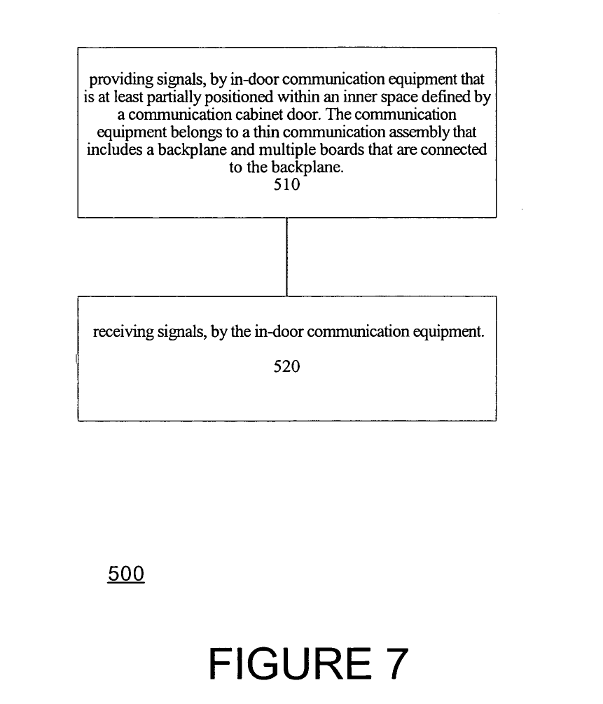

FIG. 7 is a flow chart of a method 500 for exchanging electrical signals, according to an embodiment of the invention. Method 500 starts by stage 510 of providing signals, by inner door space communication equipment that is at least partially positioned within an inner space defined by a communication cabinet door. The communication equipment belongs to a thin communication assembly that includes a backplane and multiple boards that are connected to the backplane.

According to an embodiment of the invention the signals can include telecommunication signals such as optical or electromagnetic signals, they can also include power signals. Conveniently, the inner door space communication equipment exchanges signals with inner cabinet communication signals and/or with equipment located outside the communication cabinet, via cables.

Stage 510 is followed by stage 520 of receiving signals, by the inner door space communication equipment.

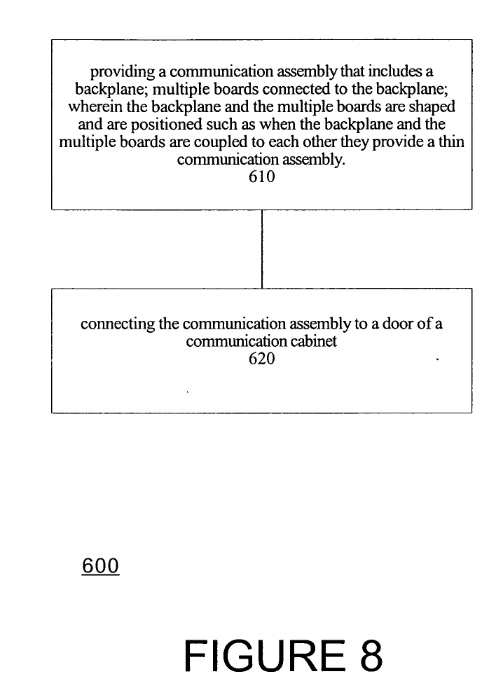

In is noted that the various stages of FIGS. 7 and 8 can be executed in parallel to each other and the order of the stages can be reversed.

FIG. 8 is a flow chart of a method 600 for installing a communication assembly, according to an embodiment of the invention.

Method 600 starts by stage 610 of providing a communication assembly that includes a backplane; multiple boards connected to the backplane; wherein the backplane and the multiple boards are shaped and are positioned such as when the backplane and the multiple boards are coupled to each other they provide a thin communication assembly.

Stage 610 is followed by stage 620 of connecting the communication assembly to a door of a communication cabinet. The connecting stage can include any known manner for connecting electronic equipment and/or the housing to the door. This can include connecting the equipment and/or the housing by screws, fasteners and the like. The connecting stage can include an installation of shock absorbers, the connection of fans and the like. This stage may also include electrically connecting the communication equipment to the door. Typically the stage of connecting also may include a stage of checking the inner door space communication equipment.

According to an embodiment of the invention the communication equipment includes a residual power source such as a battery. The battery can provide power during relatively periods of power failures.

Those of skill in Variations, modifications, and other implementations of what is described herein will occur to those of ordinary skill in the art without departing from the spirit and the scope of the invention as claimed. Accordingly, the invention is to be defined not by the preceding illustrative description but instead by the spirit and scope of the following claims.

We claim:

1. A communication assembly, comprising:
a backplane; and
multiple boards coupled to the backplane such that at least one board is coupled to one side of the backplane while at least one other board is coupled to a second side of the backplane;
wherein the backplane and the multiple boards are shaped and are positioned such as when the backplane and the multiple boards are coupled to each other they provide a thin communication assembly.

2. The communication assembly of claim 1 wherein the thin communication assembly fits into a thin space.

3. The communication assembly of claim 2 wherein the thin space corresponds to inner door space defined by inner walls of a door of a communication cabinet.

4. The communication assembly of claim 1 wherein the backplane is connected to at least one board such as to provide structural support to the at least one board.

5. The communication assembly of claim 1 wherein at least two rows of boards are connected to a single side of the backplane.

6. The communication assembly of claim 1 further comprising shock absorbers adapted to reduce mechanical impacts.

7. The communication assembly of claim 1 further comprising a housing.

8. The communication assembly of claim 7 wherein the housing at least partially surround the backplane and the multiple boards.

9. The communication assembly of claim 1 further comprising at least one fan adapted to cool at least one board.

10. A communication cabinet, comprising:
a door that comprises inner walls that define a substantially shallow inner door space, and
a communication cabinet that comprises a backplane and multiple boards coupled to the backplane; wherein the backplane and the multiple boards are shaped and are positioned such as to fit within the inner door space.

11. The communication cabinet of claim 10 wherein the communication assembly is substantially confined within the inner door space.

12. The communication cabinet of claim 10 wherein the backplane is connected to at least one board such as to provide structural support to the at least one board.

13. The communication cabinet of claim 10 wherein at least two rows of boards are connected to a single side of the backplane.

14. A method for exchanging electrical signals, the method comprises:
providing signals to inner door space communication equipment that is at least partially positioned within an inner space defined by a communication cabinet door; and
receiving signals from the inner door space communication equipment;
wherein the inner door space communication equipment comprises a backplane and multiple boards coupled to the backplane.

15. The method of claim 14 wherein the backplane is connected to at least one board such as to provide structural support to the at least one board.

16. The method of claim 14 wherein at least two rows of boards are connected to each of two sides of the backplane.

17. The method of claim 14 wherein the receiving comprises receiving signals by inner cabinet communication equipment.

18. The method of claim 14 wherein the receiving comprises receiving signals by equipment located outside the communication cabinet.

19. A method for exchanging electrical signals, the method comprises:
providing signals, by inner door space communication equipment that is at least partially positioned within an inner space defined by a communication cabinet door;
wherein the communication equipment comprises a backplane and multiple boards that are coupled to the backplane; and
receiving signals, by the inner door space communication equipment.

20. The method of claim 19 wherein the backplane is connected to at least one board such as to provide structural support to the at least one board.

21. The method of claim 19 wherein the receiving comprises receiving signals from inner cabinet communication equipment.

22. The method of claim 19 wherein the receiving comprises receiving signals from equipment located outside the communication cabinet.

23. A method for installing a communication assembly, the method comprises:
providing a communication assembly that includes a backplane and multiple boards coupled to the backplane;
wherein the backplane and the multiple boards are shaped and are positioned such as when the backplane and the multiple boards are coupled to each other they provide a thin communication assembly; and
connecting the communication assembly to a door of a communication cabinet.

24. The method of claim 23 wherein the backplane is connected to at least one board such as to provide structural support to the at least one board.

25. The method of claim 24 wherein the backplane is substantially perpendicular to at least one board.
